(19) United States
(12) Patent Application Publication
(10) Pub. No.: US 2017/0077435 A1
(43) Pub. Date: Mar. 16, 2017

(54) DISPLAY PANEL, ORGANIC LIGHT EMITTING DIODE AND METHOD FOR MANUFACTURING THE SAME

(71) Applicants: TIANMA MICRO-ELECTRONICS CO., LTD., Shenzhen (CN); SHANGHAI TIANMA AM-OLED CO., LTD., Shanghai (CN)

(72) Inventor: Zaifeng XIE, Shanghai (CN)

(73) Assignees: SHANGHAI TIANMA AM-OLED CO., LTD., Shanghai (CN); TIANMA MICRO-ELECTRONICS CO., LTD., Shenzhen (CN)

(21) Appl. No.: 14/966,459

(22) Filed: Dec. 11, 2015

(30) Foreign Application Priority Data
Sep. 11, 2015 (CN) 201510575613.2

(51) Int. Cl. H01L 51/50; H01L 51/52; H01L 27/32; H01L 51/56; H01L 51/00

(52) U.S. Cl. CPC H01L 51/5008; H01L 51/5012; H01L 51/5056; H01L 51/5088; H01L 51/56; H01L 51/001; H01L 27/3244; H01L 51/524; H01L 51/5004; H01L 2227/323; H01L 51/0037; H01L 51/0042; H01L 2251/552; H01L 2251/303

(57) ABSTRACT

A display panel, a polymer light emitting diode and a method for manufacturing the same are provided. The polymer light emitting diode has: an organic light emitting layer having a first surface and a second surface opposite to each other; an electron transport part formed on the first surface of the organic light emitting layer, and a hole transport part formed on the second surface of the organic light emitting layer. The hole transport part has a hole injection layer and a hole transport layer formed in sequence. The hole transport part further has an intermediate energy level layer having an energy level. The energy level of the intermediate energy level layer ranges between energy levels of two membrane layers sandwiching the intermediate energy level layer.

### CROSS-REFERENCE TO RELATED APPLICATIONS

This application is based upon and claims priority to Chinese Patent Application 201510575613.2, filed Sep. 11, 2015, the entire contents of which are incorporated herein by reference.

### TECHNICAL FIELD

The present disclosure generally relates to fields of display technology, and more particularly, to an organic light emitting diode, a method for manufacturing the organic light emitting diode, and a display panel including the organic light emitting diode.

### BACKGROUND

With rapid development of science and technology, demands for display panels are increasingly increased, which tend to become lighter and thinner with less power consumed. Accordingly, there emerges organic light emitting diode (OLED) display panel. Compared to conventional liquid crystal display panel, the OLED display panel is self-luminous without backlight module having high energy consumption and, hence, is lighter and thinner with less power consumed. Thus, more and more attention is paid to the OLED display panel.

Depending on different organic light emitting material adopted, OLED in the OLED display panel may be classified into small molecule light emitting diode (SMLED) and polymer light emitting diode (PLED). In comparison, the SMLED may be manufactured with a vacuum thermal evaporator having high cost and not suit for application in large area display panels, while the PLED may be manufactured more easily with reduced costs on equipments and process via wet methods such as solution spin coating or droplet coating, and suit for application in the large area display panels.

A proper device structure is of key importance in improving characteristics of the PLED such as brightness, current efficiency and stability. Referring to FIG. 1, which illustrates a block diagram of a conventional PLED, the PLED mainly includes a hole transport part 1′, an organic light emitting layer 2′ and an electron transport part 3′ stacked sequentially. Principle for the PLED to emit light may be described as follows. Holes injected through the hole transport part 1′ are combined with electrons injected through the electron transport part 3′ in the organic light emitting layer 2′ to generate excitons so as to emit light. Herein, the hole transport part 1′ and the electron transport part 3′ serve mainly to address imbalance between injections of two types of carries, wherein the hole transport part 1′ may include an anode 10′, a hole injection layer (HIL) 11′ and a hole transport layer (HTL) 12′, while the electron transport part 3′ may include a cathode 30′ and an electron transport layer (ETL) 31′, and may further include an electron injection layer (EIL) in certain kinds of PLED (not shown).

However, it is desirable to improve current efficiency of conventional PLEDs.

### SUMMARY

The present disclosure is directed to provide a polymer light emitting diode, a method for manufacturing the polymer light emitting diode, and a display panel including the polymer light emitting diode, such that one or more problems caused by limitation or defects in related art may be overcome to a certain extent.

Other features and advantages of the disclosure may be apparent through detailed description hereinafter, or may be obtained through implementation thereof.

According to a first aspect the present disclosure, there is provided a polymer light emitting diode, including:

an organic light emitting layer having a first surface and a second surface opposite to each other;

an electron transport part formed on the first surface of the organic light emitting layer, and

a hole transport part formed on the second surface of the organic light emitting layer, comprising a hole injection layer and a hole transport layer stacked in sequence;

wherein the hole transport part further comprises an intermediate energy level layer, an energy level of the intermediate energy level layer ranging between energy levels of two layers sandwiching the intermediate energy level layer.

According to a second aspect the present disclosure, there is provided a method for manufacturing a polymer light emitting diode, including:

forming a hole transport part configured to provide hole carriers;

forming an organic light emitting layer on the hole transport part; and

forming an electron transport part, configured to provide electron carriers, on the organic light emitting layer;

wherein the forming the hole transport part comprises:

forming a hole injection layer;

forming a hole transport layer; and

forming an intermediate energy level layer having an energy level, wherein the energy level of the intermediate energy level layer ranges between energy levels of two membrane layers sandwiching the intermediate energy level layer.

According to an embodiment of the second aspect the present disclosure, there is provided a method for manufacturing a polymer light emitting diode, including:

forming a hole transport part configured to provide hole carriers;

forming an organic light emitting layer on the hole transport part; and

forming an electron transport part, configured to provide electron carriers, on the organic light emitting layer;

wherein the forming the hole transport part comprises:

forming a hole injection layer;

forming an intermediate energy level layer on the hole injection layer; and

forming a hole transport layer on the intermediate energy level layer, an energy level of the intermediate energy level layer ranging between energy levels of two membrane layers adjacent to the intermediate energy level layer.

According to another embodiment of the second aspect the present disclosure, there is provided a method for manufacturing a. polymer light emitting diode, including:

forming a hole transport part configured to provide hole carriers;

forming an organic light emitting layer on the hole transport part; and

forming an electron transport part, configured to provide electron carriers, on the organic light emitting layer;

wherein the forming the hole transport part comprises:

forming a hole injection layer;

forming a hole transport layer on the hole injection layer; and

forming an intermediate energy level layer on the hole transport layer, an energy level of the intermediate energy level layer ranging between energy levels of the hole transport layer and the organic light emitting layer.

According to a third aspect the present disclosure, there is provided a display panel, including:

a first substrate;

a second substrate provided opposite to the first substrate;

a polymer light emitting diode as described above, provided between the first substrate and the second substrate; and

a seal member provided around the first substrate and the second substrate and configured to package the organic light emitting diode between the first substrate and the second substrate.

In the present exemplary embodiment, an intermediate energy level layer with an energy level between two membrane layers adjacent thereto is provided in the hole transport part, so as to reduce energy barrier and internal electric filed effect between interfaces of both membrane layers adjacent thereto. Accordingly, more hole carriers can be facilitated to be transported to the organic light emitting layer and, thus, current efficiency of the PLED can be improved.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments consistent with the invention and, together with the description, serve to explain the principles of the invention.

Features and advantages of the present disclosure described above as well as other features and advantages thereof may become more apparent through detailed description of exemplary embodiments by reference to the accompanying drawings.

FIG. 1 is block diagram illustrating a PLED in prior art.

FIG. 2 is a block diagram illustrating a PLED according to an exemplary embodiment of the present disclosure.

FIG. 3 is a block diagram illustrating a PLED according to another exemplary embodiment of the present disclosure.

FIG. 4 is a flow chart illustrating a method for manufacturing the PLED according to FIG. 3.

FIGS. 5A-5B illustrate correspondence between rotary speeds and membrane thicknesses with different solution concentrations in spin coating process according to an exemplary embodiment.

FIG. 6 is a block diagram illustrating a PLED according to yet another exemplary embodiment of the present disclosure.

FIG. 7 is a flow chart illustrating a method for manufacturing the PLED according to FIG. 6.

FIG. 8 is a block diagram illustrating a PLED according to still another exemplary embodiment of the present disclosure.

### DETAILED DESCRIPTION

Description will now be made in detail to exemplary embodiments by reference to the accompanying drawings. However, the exemplary embodiments may be implemented in various ways rather than being understood as limited to those embodiments described herein. Instead, those embodiments are provided to illustrate the disclosure comprehensively and completely, and to deliver concept of the exemplary embodiments entirely to those skilled in the art. Like elements are represented by like reference signs in the drawings, and detailed description thereof may be omitted.

Furthermore, features, structures or properties described herein may be combined into one or more embodiments in any proper ways. Detailed description will be made hereinafter to enable the embodiments of the disclosure to be comprehensible. However, it should be noted for those skilled in the art, technical solution of the disclosure may be implemented by means of alternative structures, materials or processes instead of one or more of those specific elements described herein. Otherwise, structures, processes or operations well known in the art may be not illustrated or described herein for fear of obscuring aspects of the disclosure.

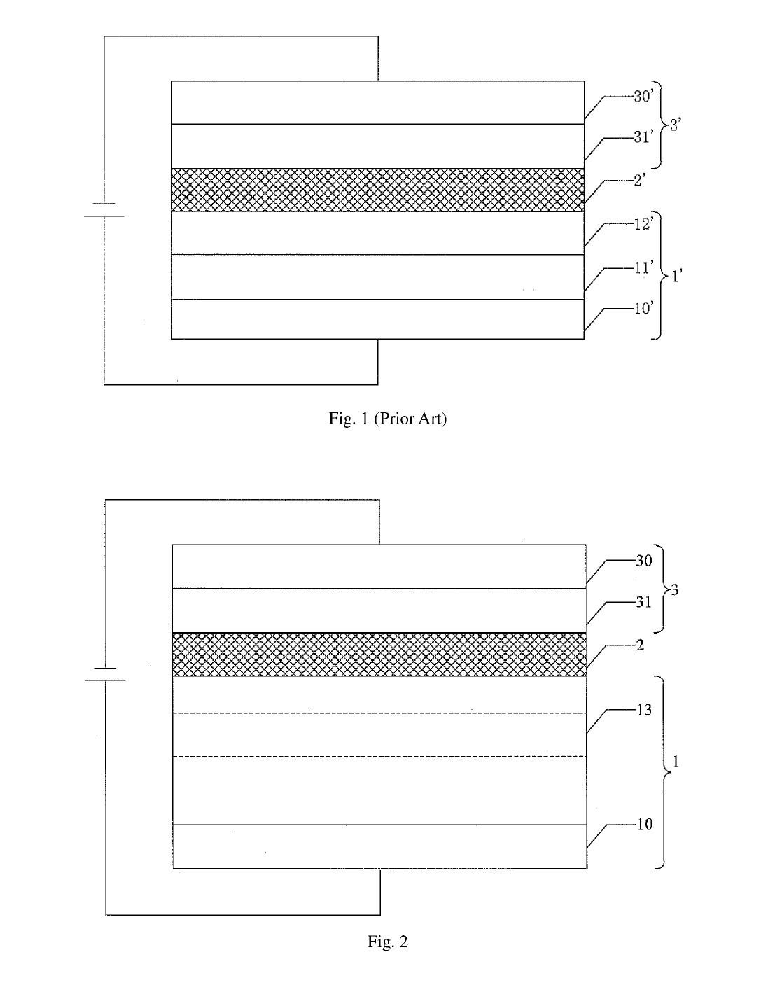

There is provided a PLED in the exemplary embodiments. PLEDs may be classified into a bottom emission type and a top emission type depending on direction of light emission. Taking the bottom emission type for an example, referring to FIG. 2, the PLED includes mainly a hole transport part 1, an organic light emitting layer 2 and an electron transport part 3. Herein, the organic light emitting layer 2 includes a first surface and a second surface (for example upper side surface and lower side surface as shown in the drawing) opposite to each other. The hole transport part 1 is stacked on the lower side surface of the organic light emitting layer 2, and includes an anode 10, a hole injection layer (not shown) and a hole transport layer (not shown). The electron transport part 3 is stacked on the upper side surface of the organic light emitting layer 2, and includes an electron transport layer 31 and a cathode 30. The anode 10 may be made from materials with high work function and good transparency, for example transparent conductive oxides such as transparent ITO (Indium Tin Oxide) conductive membrane. The cathode 30 may be made from transparent conductive materials, for example Al, Ca, In or Mg—Al alloy transparent conductive membrane. In addition, the hole transport 1 further includes an intermediate energy level layer 13, an energy level of which lies between energy levels of two membrane layers adjacent thereto.

Low current efficiency of PLEDs may arise from inherent defect of polymer light emitting materials with low internal quantum efficiency, as well as lack of existing materials for the hole transport part 1 having high performance. For example, such materials may include mainly PETDOT: PSS ((3,4-ethylenedioxythiophene)-polystyrene sulfonic acid) and PVK (polyvinyl carbazole). However, for a hole transport part 1 made from those materials, energy barrier between membrane layers therein is relatively high. Accordingly, hole carries may accumulate excessively at interfaces to form internal electric field and, hence, the number of excitons generated is reduced. According to the present exemplary embodiments, the intermediate energy level layer 13 with an energy level between two membrane layers adjacent thereto is provided in the hole transport part 1, so as to reduce the energy barrier and internal electric filed effect between interfaces of both membrane layers adjacent thereto. Accordingly, more hole carriers can be facilitated to be transported to the organic light emitting layer 2 and, thus, current efficiency of the PLED can be improved.

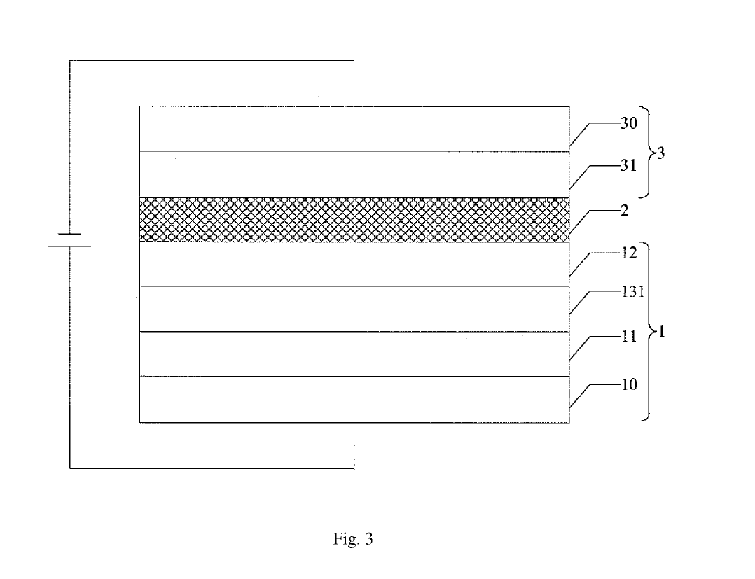

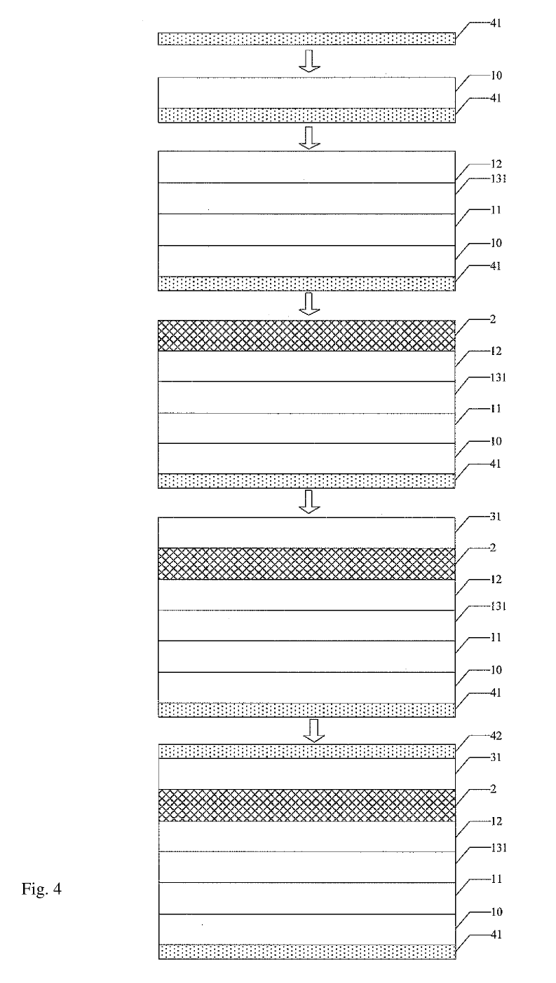

Referring to FIG. 3, the intermediate energy level layer 13 may include a first intermediate energy level layer 131 provided between the hole injection layer (HIL) 11 and the hole transport layer (HTL) 12. For example, the HIL 11 may include (3,4-ethylenedioxythiophene)-polystyrene sulfonic acid and the like, while the HTL 12 may include polyvinyl carbazole and derivations thereof, and may also include polymethylphenethylsilane (PMPS), other polymer containing triarylamine side chain or bridged triaryl side chain (for example, P-TPD, P-NPD), or the like. The first intermediate energy level layer 131 may have a work function (e.g. 5.3 eV-5.7 eV) greater than HOMO energy level (e.g. 5.2 eV) of the HIL 11 and smaller than HOMO energy level (e.g. 5.8 eV) of the HTL 12. Accordingly, impact of energy barrier between the HIL 11 and the HTL 12 can be reduced such that energy level can transit more smoothly between the MIL 11 and the HTL 12 and, hence, hole carriers can be more easily injected into the HTL 12. The first intermediate energy level layer 131 may include P-type metal oxide or polymer organic compound. For example, the first intermediate energy level layer 131 is P-type metal oxide, it may include materials with proper work function, such as MoO₃ or Ni₂O₃, to satisfy requirement of energy level described above and for facilitation of process requirements related to subsequent solution process or spin coating. Referring to FIG. 4, which illustrates a method for manufacturing the PLED according to FIG. 3, the method includes mainly following steps.

A first substrate 41, which may include rigid or flexible substrate formed of glass, silicon wafer, quartz, plastic or the like, is provided.

Then, the hole transport part 1 is formed on the first substrate 41 to provide hole carriers. Steps of forming the hole transport part 1 may be included as follows.

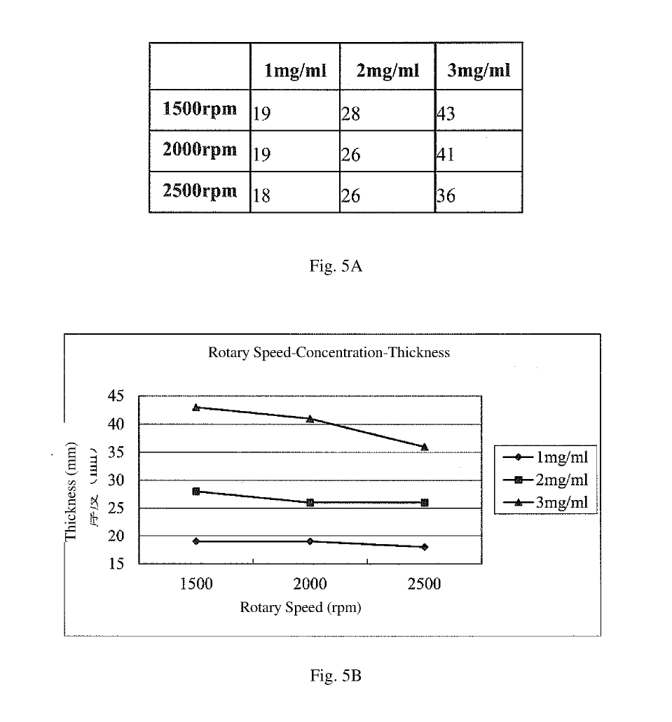

Forming an electrode of the anode 10, for example, a transparent ITO conductive membrane, on the first substrate 41 by means of processes such as vapor deposition; forming the HIL 11 on the anode 10, wherein the HIL 11 may include (3,4-Ethylenedioxythiophene)-polystyrene sulfonic acid and the like; and forming the first intermediate energy level layer 131, which may include materials having proper work functions, such as MoO₃ or Ni₂O₃, on the HIL 11. In the present exemplary embodiment, for purpose of cost reduction, the first intermediate energy level layer 131 may be obtained by means of collosol-gelling process and further formed on the HIL 11 by means of solution process such as spin coating or inkjet printing. As shown in FIGS. 5A-5B, correspondence between the rotary speeds and membrane thicknesses with different solution concentrations in spin coating process is illustrated. Accordingly, the first intermediate energy level layer 131 can be formed with different thicknesses by adjusting the solution concentration and the rotary speed. It should be understood by those skilled in the art, however, the first intermediate energy level layer 131 may be also formed on the HIL 11 through other processes such as vacuum heat vapor deposition in alternative exemplary embodiments of the disclosure. Furthermore, the HTL 12, which may include polyvinyl carbazole or the like, is formed on the first intermediate energy level layer 131.

The organic light emitting layer 2 is formed on the hole transport part 1 and may include polyfluorene and derivatives thereof, polyvinyl carbazole, poly (2-(4-(3′,7′-dimethyloctyloxy benzene)-1,4-phenylene vinylene) and the like.

The electron transport layer 31 is formed on the organic light emitting layer 2 to provide electron carriers. Moreover, the cathode 30, which may be made from transparent conductive materials, for example Al, Ca, In or Mg—Al alloy transparent conductive membrane, is formed on the electron transport layer 31.

Finally, the PLED is obtained through a package of the first substrate 41, a second substrate 42 and a seal member (not shown). An intermediate energy level may he provided in polymer materials of a PLED with tri-color R, G, B, or may be extended to polymer materials of a PLED with single color, for example, MEH-PPV emitting red light, P-PPV emitting green light, or PVK or PFO emitting blue light.

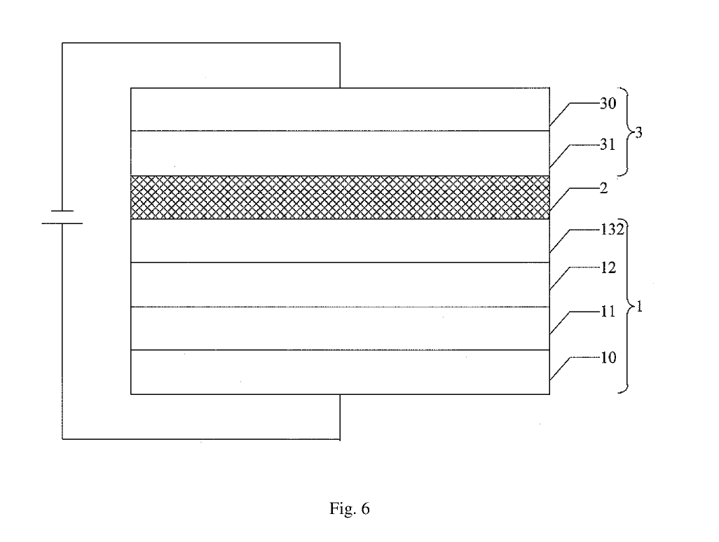

As shown in FIG. 6, the intermediate energy level layer 13 may also include a second intermediate energy level layer 132 provided between the HTL 12 and the organic light emitting layer 2. For example, the HTL 12 may include polyvinyl carbazole or the like, while the organic light emitting layer 2 may include polyfluorene and derivatives thereof, polyvinyl carbazole, poly (2-(4-(3′,7′-dimethyloctyloxy benzene)-1,4-phenylene vinylene) or the like. The second intermediate energy level layer 132 may have a work function (e.g. 5.3 eV-5.7 eV) greater than HOMO energy level (e.g. 5.3 eV) of the organic light emitting layer 2 and smaller than HOMO energy level (e.g. 5.8 eV) of the HTL 12. Accordingly, impact of energy barrier between the HTL 12 and the organic light emitting layer 2 can be reduced such that energy level can transit more smoothly therebetween and, hence, hole carriers can be more easily injected into the organic light emitting layer 2. The second intermediate energy level layer 132 may also include P-type metal oxide or polymer organic compound. For example, the second intermediate energy level layer 132 is P-type metal oxide, it may include materials with proper work function, such as MoO₃ or Ni₂O₃, to satisfy requirement of energy level described above and for facilitation of process requirements related to subsequent solution process or spin coating.

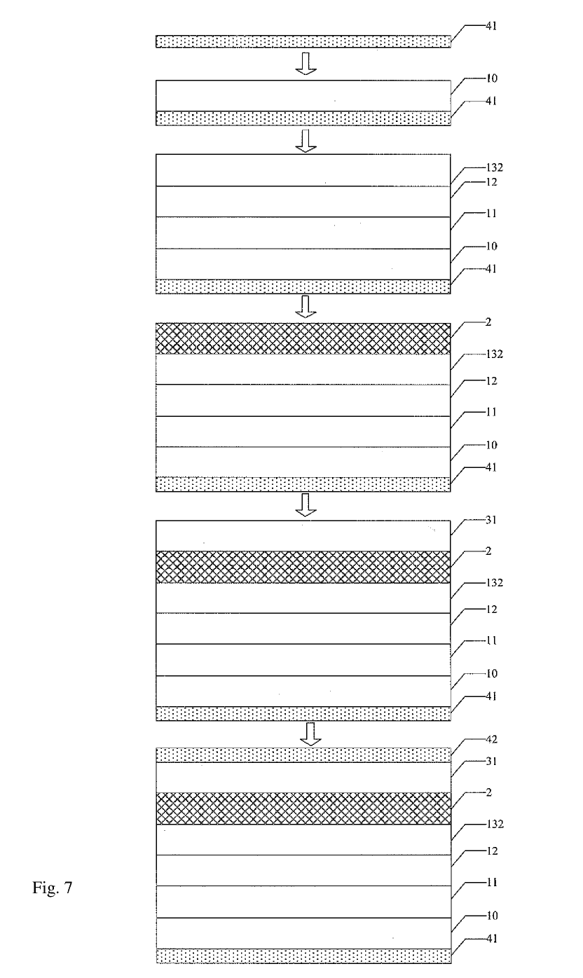

Referring to FIG. 7, which illustrates a method for manufacturing the PLED according to FIG. 6, the method includes mainly following steps.

A first substrate 41, which may include rigid or flexible substrate formed of glass, silicon wafer, quartz, plastic or the like, is provided.

Then, the hole transport part 1 is formed on the first substrate 41 to provide hole carriers. Steps of forming the hole transport part 1 may be included as follows.

Forming an electrode of the anode 10, for example, a transparent ITO conductive membrane, on the first substrate 41 by means of processes such as vapor deposition; forming the HIL 11 on the anode 10, wherein the HIL 11 may include (3,4-Ethylenedioxythiophene)-polystyrene sulfonic acid and the like; forming the HTL 12, which may include polyvinyl carbazole or the like, on the first intermediate energy level layer 131; and forming the second intermediate energy level layer 132, which may include materials having proper work function, such as MoO₃ or Ni₂O₃, on the HTL 12. In the present exemplary embodiment, for purpose of cost reduction, the second intermediate energy level layer 132 may be obtained by means of collosol-gelling process and further formed on the HTL 12 by means of solution process such as spin coating or inkjet printing. As shown in FIGS. 5A-5B, correspondence between the rotary speeds and membrane thicknesses with different solution concentrations in spin coating process is illustrated. Accordingly, the first intermediate energy level layer 131 can be formed with different thicknesses by adjusting the solution concentration and the rotary speed. It should be understood by those skilled in the art, however, the second intermediate energy level layer 132 may be also formed on the HTL 12 through other processes such as vacuum heat vapor deposition in alternative exemplary embodiments of the disclosure.

The organic light emitting layer 2 is formed on the second intermediate energy level layer 132 and may include polyfluorene or derivatives thereof, polyvinyl carbazole, poly (2-(4-(3′,7′-dimethyloctyloxy benzene)-1,4-phenylene vinylene) or the like.

The electron transport layer 31 is formed on the organic light emitting layer 2 to provide electron carriers. Moreover, the cathode 30, which may be made from transparent conductive materials, for example Al, Ca, In or Mg—Al alloy transparent conductive membrane, is formed on the electron transport layer 31. Processes described above may be understood by reference to related art, and details of which are omitted herein.

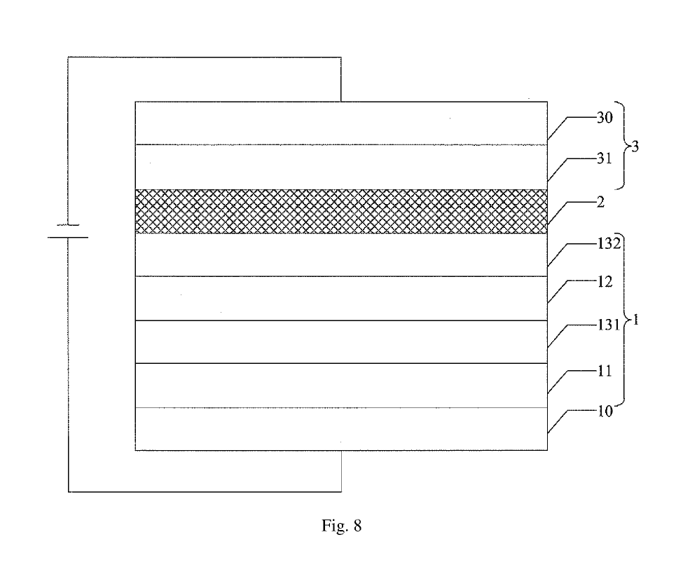

Referring to FIG. 8, the intermediate energy level 13 may also include both the first intermediate energy level 131 and the second intermediate energy level 132. Detailed description for the first and second intermediate energy level 131 and 132 and preparation thereof are given as above and omitted herein.

Furthermore, in order to better understand advantages of the disclosure, experimental tests are further conducted aiming at the performance of the OLED with the intermediate energy level layer according to the exemplary embodiments. As shown in following Table 1, an intermediate energy level made from MoO₃ is provided between the HTL 12 and the organic light emitting layer 2 in the OLED according to experimental example 1; an intermediate energy level made from Ni₂O₃ is provided between the HTL 12 and the organic light emitting layer 2 in the OLED according to experimental example 2; and there is no intermediate energy level provided between the HTL 12 and the organic light emitting layer 2 in the OLED according to experimental example 3. Experimental results are obtained as shown in following Table 2.

TABLE 1

| | Current efficiency | |
|---|---|---|
| Experimental example | cd/A@100 nits | Threshold voltage V |
| Experimental example 1 | 16.45 | 3.5 |
| Experimental example 2 | 13.23 | 3.4 |
| Experimental example 3 | 1.28 | 7 |

As can be seen from Table 1, compared to conventional OLEDs with a threshold voltage of 7V, a threshold voltage of the OLED according to the present exemplary embodiments can be reduced to 3.4 V or 3.5 V. As far as current efficiency is concerned, the OLEDs has a current efficiency raised from 1.28 cd/A to 13.23 cd/A or 16.45 cd/A due to improvement of energy level transition. That is, the current efficiency is substantially improved.

Furthermore, there is provided a display panel in the present exemplary embodiment. The display panel includes a first substrate, a second substrate, a seal member and the PLED described above. The first substrate and the second substrate are provided opposite to each other. The organic light emitting diode is provided between the first substrate and the second substrate. The seal member is provided around the first substrate and the second substrate and configured to package the organic light emitting diode between the first substrate and the second substrate. Display quality and energy efficiency of the display panel can be improved due to relatively high current efficiency of the PLED.

The disclosure has been described by reference to the embodiments above which are merely examples for implementing the disclosure. It should be noted that the present disclosure is not limited to the exact embodiments that have been described above. Instead, various modifications and changes can be made without departing from concept and scope of the disclosure and should be covered by protection scope thereof.

What is claimed is:

1. A polymer light emitting diode comprising:
an organic light emitting layer having a first surface and a second surface opposite to each other;
an electron transport part formed on the first surface of the organic light emitting layer, and
a hole transport part formed on the second surface of the organic light emitting layer, the hole transport part comprising a hole injection layer, a hole transport layer and an intermediate energy level layer having an energy level,
wherein the energy level of the intermediate energy level layer ranges between energy levels of two layers sandwiching the intermediate energy level layer.

2. The polymer light emitting diode of claim 1, wherein the intermediate energy level layer comprises:
a first intermediate energy level layer provided between the hole injection layer and the hole transport layer, and/or
a second intermediate energy level layer provided between the hole transport layer and the organic light emitting layer.

3. The polymer light emitting diode of claim 2, wherein the first intermediate energy level layer has a first energy level and the first energy level is greater than an energy level of the hole injection layer and smaller than an energy level of the hole transport level.

4. The polymer light emitting diode of claim 2, wherein the second intermediate energy level layer has a second energy level and the second energy level is greater than an energy level of the organic light emitting layer and smaller than an energy level of the hole transport level.

5. The polymer light emitting diode of claim 2, wherein the first intermediate energy level layer comprises P-type metal oxide or polymer organic compound.

6. The polymer light emitting diode of claim 5, wherein the first intermediate energy level layer comprises P-type metal oxide.

7. The polymer light emitting diode of claim 6, wherein the first intermediate energy level layer comprises MoO₃ or Ni₂O₃.

8. The polymer light emitting diode of claim 2, wherein the second intermediate energy level layer comprises P-type metal oxide or polymer organic compound.

9. The polymer light emitting diode of claim 8, wherein the second intermediate energy level layer comprises P-type metal oxide.

10. The polymer light emitting diode of claim 9, wherein the second intermediate energy level layer comprises MoO₃ or Ni₂O₃.

11. The polymer light emitting diode of claim 1, wherein the hole injection layer comprises (3,4-ethylenedioxythiophene)-polystyrene sulfonic acid.

12. The polymer light emitting diode of claim 1, wherein the hole transport layer comprises polyvinyl carbazole or derivatives thereof.

13. The polymer light emitting diode of claim 1, wherein the organic light emitting layer comprises polyfluorene or derivatives thereof, polyvinyl carbazole, or poly (2-(4-(3′,7′-dimethyoctyloxy benzene)-1,4-phenylene vinylene).

14. A method for manufacturing a polymer light emitting diode, the method comprising:
forming a hole transport part configured to provide hole carriers;
forming an organic light emitting layer on the hole transport part; and
forming an electron transport part on the organic light emitting layer, electron transport part configured to provide electron carriers;
wherein the forming the hole transport part comprises:
forming a hole injection layer;
forming a hole transport layer; and
forming an intermediate energy level layer having an energy level, wherein the energy level of the intermediate energy level layer ranges between energy levels of two layers sandwiching the intermediate energy level layer.

15. The method of claim 14, wherein the forming the intermediate energy level layer comprises:
forming a first intermediate energy level layer between the hole injection layer and the hole transport layer, and/or
forming a second intermediate energy level layer between the hole transport layer and the organic light emitting layer.

16. The method of claim 15, wherein the first intermediate energy level layer has a first energy level that is greater than an energy level of the hole injection layer and smaller than an energy level of the hole transport level.

17. The method of claim 16, wherein the first intermediate energy level layer is formed on the hole injection layer by means of vacuum heat vapor deposition or collosol-gelling.

18. The method of claim 15, wherein the second intermediate energy level layer has a second energy level that is greater than an energy level of the organic light emitting layer and smaller than an energy level of the hole transport level.

19. The method of claim 18, wherein the second intermediate energy level layer is formed on the hole transport layer by means of vacuum heat vapor deposition or collosol-gelling process.

20. A polymer light emitting display panel comprising:
a first substrate;
a second substrate provided opposite to the first substrate;
an organic light emitting diode according to claim 1, provided between the first substrate and the second substrate; and a seal member provided around the first substrate and the second substrate and configured to package the organic light emitting diode between the first substrate and the second substrate.
